(19) United States
(12) Patent Application Publication
(10) Pub. No.: US 2026/0344498 A1
(43) Pub. Date: Oct. 29, 2026

(54) HYBRID BONDING TECHNIQUES THAT UTILIZE MULTI-FUNCTIONAL BARRIER MATERIALS

(71) Applicant: Micron Technology, Inc., Boise, ID (US)

(72) Inventor: Ying-Tsun Su, Taipei (TW)

(21) Appl. No.: 19/631,970

(22) Filed: Mar. 27, 2026

Related U.S. Application Data
(60) Provisional application No. 63/794,250, filed on Apr. 24, 2025.

(51) Int. Cl. H10W 72/90; H10W 80/00; H10W 90/00

(52) U.S. Cl. CPC H10W 72/923; H10W 72/952; H10W 72/953; H10W 80/312; H10W 90/792

(57) ABSTRACT

Semiconductor devices with dual-function barrier layers for hybrid bonding are disclosed herein. A semiconductor device can include a first substrate having a first dielectric layer and first bond pads disposed thereon, a second substrate having a second dielectric layer and second bond pads disposed thereon, and a barrier layer disposed between portions of corresponding first and second bond pads. The first substrate can be hybrid bonded to the second substrate via the dielectric layers and bond pads. The barrier layer can be configured to inhibit diffusion and/or migration of conductive material from the first bond pad into the second dielectric layer and/or from the second bond pad into the first dielectric layer. The barrier layer can comprise platinum group metals, two-dimensional materials, or graphene-modified copper materials, and can promote diffusion between corresponding bond pads while inhibiting diffusion into dielectric layers.

### CROSS-REFERENCE TO RELATED APPLICATION(S)

The present application claims priority to U.S. Provisional Patent Application No. 63/794,250, filed Apr. 24, 2025, the disclosure of which is incorporated herein by reference in its entirety.

### TECHNICAL FIELD

This disclosure relates generally to semiconductor packaging. For example, several embodiments of the present technology described in greater detail below are generally related to hybrid bonding techniques that utilize barrier materials over metal contacts, such as to prevent contact oxidation and/or conductor diffusion in the event of misaligned interconnects.

### BACKGROUND

Semiconductor devices have become increasingly complex and miniaturized, driving the need for advanced packaging technologies. Hybrid bonding has emerged as a promising technique for achieving high-density interconnects in three-dimensional semiconductor device assemblies. This process combines both dielectric and metallic bonding to achieve high-density interconnects between stacked substrates. Hybrid bonding can enhance electrical performance and thermal management, making it ideal for applications requiring high bandwidth and/or low power consumption. It is particularly significant in three-dimensional (3D) integration techniques, in which it enables the stacking of multiple layers of substrates with strong mechanical integrity.

One challenge in hybrid bonding is the potential for misalignment between the metal contacts ("bond pads") on the two substrates being bonded. Manufacturing tolerances, equipment limitations, and differences in bond pad sizes can result in slight offsets between corresponding bond pads. This misalignment can lead to unintended interfaces between metal of the bond pads and dielectric materials. As many metals readily diffuse into silicon and other dielectric materials that are commonly used in semiconductor fabrication, the unintended interfaces can compromise electrical and/or mechanical integrity of a semiconductor device in the event of diffusion and/or migration during or after hybrid bonding. In addition, many metals are particularly susceptible to oxidation when exposed to air, which can compromise intended electrical connections formed between bond pads during hybrid bonding.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1A is a partially schematic cross-sectional side view of a semiconductor device configured in accordance with various embodiments of the present technology.

FIG. 1B is a partially schematic zoomed-in view of an interconnect configured in accordance with various embodiments of the present technology and corresponding to a breakaway section of FIG. 1A.

FIG. 2 is a flow diagram illustrating a method of manufacturing a semiconductor device configured in accordance with various embodiments of the present technology.

FIGS. 3A–3F are partially schematic cross-sectional side views of a semiconductor device at various stages of manufacturing in accordance with various embodiments of the present technology.

FIG. 4 is a block diagram of a system including a semiconductor device, each configured in accordance with various embodiments of the present technology.

### DETAILED DESCRIPTION

The present technology generally relates to improving hybrid bonding in semiconductor device manufacturing and assembly. For example, several embodiments of the present technology described in greater detail below are directed to hybrid bonding techniques that utilize a thin film barrier layer applied to metal contacts (e.g., copper bond pads) before bonding two semiconductor substrates together. The barrier layer is expected to prevent oxidation of the metal contacts, such as before, during, and/or after performing hybrid bonding. Additionally, or alternatively, the barrier layer is expected to inhibit or prevent metal diffusion and/or migration from the metal contacts into surrounding dielectric materials, such as when corresponding metal contacts on the two substrates are misaligned during hybrid bonding and/or are differently sized (thereby leading to unintended metal-to-dielectric interfaces between the substrates). In some embodiments, the barrier layer is expected to promote metal-to-metal (e.g., copper-to-copper) diffusion between aligned portions of the metal contacts.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element’s or feature’s relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

### A. Overview

Many semiconductor devices utilize hybrid bonding techniques to achieve high-density interconnects in three-dimensional semiconductor assemblies. Hybrid bonding combines dielectric and metallic bonding to create strong mechanical and electrical connections between stacked substrates. Manufacturing tolerances, equipment limitations, and/or differently sized bond pads, however, often result in slight misalignments between corresponding metal bond pads on the substrates being bonded. This misalignment can create unintended interfaces between metal contacts and dielectric materials.

A significant challenge with hybrid bonding is that many metals used for bond pads, such as copper, are prone to diffusion and/or migration into surrounding dielectric materials like silicon. Such diffusion and/or migration can compromise the electrical and/or mechanical integrity of the semiconductor device. Additionally, metals like copper readily oxidize when exposed to air, which can interfere with forming proper electrical connections during the bonding process. Many techniques attempt to address these issues separately, such as using barrier materials to prevent metal diffusion or applying sacrificial layers to prevent oxidation. These approaches, however, often require additional processing steps and do not address both the diffusion and oxidation concerns simultaneously. For example, many techniques utilize sacrificial layers to prevent oxidation of metal contacts or bond pads, but such sacrificial layers are ineffective at preventing metal diffusion and/or migration into surrounding dielectric materials. As another example, many techniques utilize barrier materials (e.g., tantalum (Ta), tantalum nitride (TaN), titanium nitride (TiN), titanium carbide (TiC)) to prevent metal diffusion and/or migration into surrounding dielectric materials, but such materials lack properties that are effective at preventing oxidation and/or at promoting metal-to-metal diffusion.

Furthermore, many hybrid bonding techniques typically rely on high bonding temperatures, often above 300°C, to promote proper metal-to-metal bonding and overcome issues like surface oxidation. Such high temperatures, however, can introduce thermal stresses and potentially damage sensitive components within the semiconductor device. Lowering bonding temperatures while still achieving strong, reliable interconnects remains a significant challenge in the field of hybrid bonding for semiconductor packaging.

To address these concerns, the present technology is generally directed to hybrid bonding techniques that utilize a thin film barrier layer applied to metal contacts, such as copper bond pads, before bonding two semiconductor substrates together using hybrid bonding. The barrier layer is expected to serve multiple functions simultaneously, including preventing oxidation of the metal contacts and inhibiting metal diffusion and/or migration from the metal contacts into surrounding dielectric materials, particularly in cases of misalignment and/or differently sized bond pads during hybrid bonding. In some embodiments, the barrier layer also promotes metal-to-metal diffusion between aligned portions of the metal contacts. As specific examples, the thin film barrier layers can comprise materials selected from platinum group metals (e.g., platinum (Pt), palladium (Pd), ruthenium (Ru)), two-dimensional materials (e.g., graphene, hexagonal boron nitride), or graphene-modified copper materials (e.g., copper-graphene composites, copper-graphene covetics, and/or the like).

The present technology is expected to offer several advantages in comparison to other hybrid bonding techniques. For example, by inhibiting or preventing copper oxidation, the present technology is expected to enable use of lower bonding temperatures (e.g., between 200°C and 300°C), which is expected to reduce thermal stress on sensitive components. In addition, the present technology is expected to inhibit or prevent metal diffusion and/or migration into dielectric materials at misaligned interfaces, which is expected to maintain electrical and mechanical integrity of a corresponding semiconductor device, even in the event of misalignment and/or differently sized bond pads during hybrid bonding. Furthermore, by promoting metal-to-metal (e.g., copper-to-copper) diffusion across aligned portions of metal contacts or bond pads, the present technology is expected to facilitate forming stronger electrical connections between bonded substrates. Moreover, because barrier layer materials of the present technology are expected to offer two or more of these advantages simultaneously, the present technology is expected to obviate the practice of using sacrificial layers to inhibit oxidation prevention and separate barrier layers to inhibit diffusion and/or migration, thereby simplifying manufacturing processes while improving device reliability and performance.

B. Selected Embodiments of Hybrid Bonding Techniques that Utilize Multi-Functional Barrier Materials, and Associated Systems, Devices, and Methods

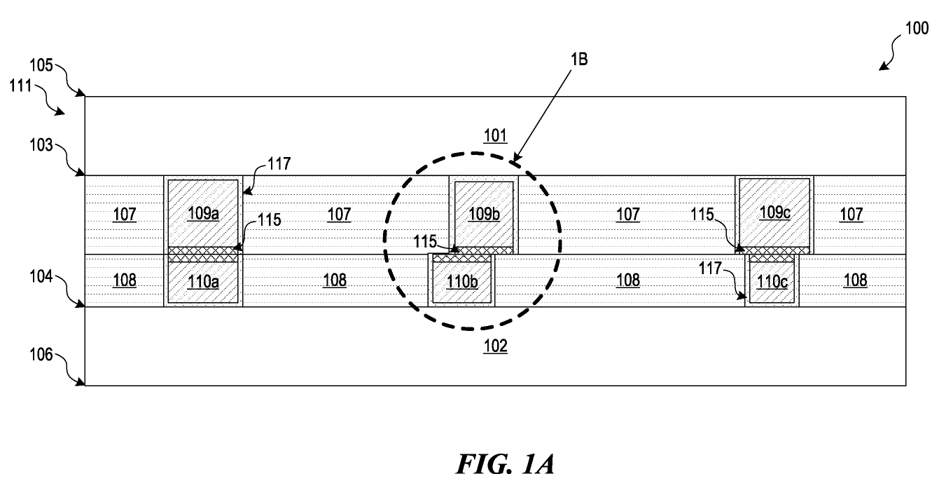

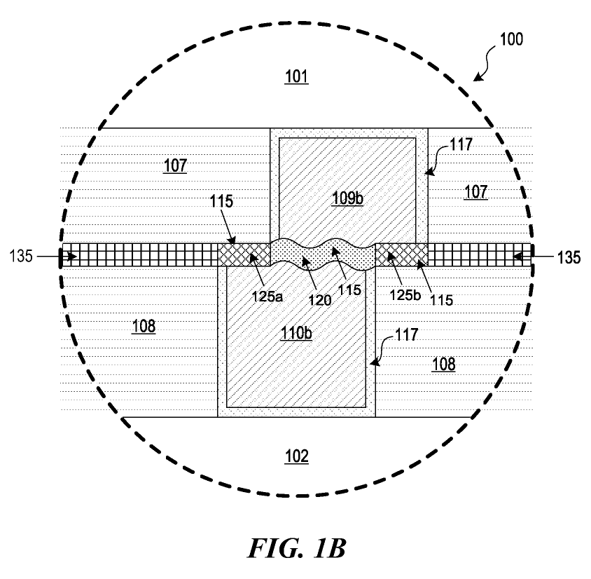

FIG. 1A is a partially schematic cross-sectional side view of a semiconductor device 100 configured in accordance with various embodiments of the present technology. As shown, the semiconductor device 100 includes (i) a first substrate 101 having a first side 103 and a second side 105 opposite the first side 103, and (ii) a second substrate 102 having a first side 104 and a second side 106 opposite the first side 104. In some embodiments, the first substrate 101 and/or the second substrate 102 can comprise a semiconductive material (e.g., silicon). The first substrate 101 can be a semiconductor wafer or a semiconductor die or chip (e.g., a memory die or chip). Additionally, or alternatively, the second substrate 102 can be a semiconductor wafer or a semiconductor die or chip.

As shown, the first substrate 101 and the second substrate 102 are arranged in a stack 111. For example, the first substrate 101 and the second substrate 102 can be arranged front-to-front, front-to-back, back-to-front, or back-to-back. As such, the first side 103 of the first substrate 101 can represent either a front side or a back side of the first substrate 101, and the first side 104 of the second substrate 102 can represent either a front side or a back side of the second substrate 102.

In the illustrated embodiment, the first substrate 101 is bonded to the second substrate 102 via a hybrid bond. More specifically, the semiconductor device 100 includes (a) a first dielectric layer 107 formed at the first side 103 of the first substrate 101, (b) a second dielectric layer 108 formed at the first side 104 of the second substrate 102, (c) a plurality of bond pads 109 (identified individually in FIG. 1A as first through third bond pads 109a-109c) disposed at the first side 103 of the first substrate 101 and/or in or on the first dielectric layer 107, and (d) a plurality of bond pads 110 (identified individually in FIG. 1A as first through third bond pads 110a-110c) disposed at the first side 104 of the second substrate 102 and/or in or on the second dielectric layer 108. The first dielectric layer 107 can be bonded to the second dielectric layer 108, and individual ones of the plurality of bond pads 109 (also referred to herein as “upper bond pads 109”) can be bonded to corresponding ones of the plurality of bond pads 110 (also referred to herein as “lower bond pads 110”).

The first dielectric layer 107 and/or the second dielectric layer 108 can be formed of one or more dielectric materials, such as silicon dioxide (SiO₂), silicon carbonitride (SiCN), silicon oxycarbide (SiOC), silicon carbide (SiC), silicon nitride (SiN), or another suitable material. Additionally, or alternatively, the bond pads 109, 110 can be formed of one or more conductive materials (e.g., copper, tungsten, or another suitable material). In some embodiments, one or more of the bond pads 109, 110 can serve as electrical contacts for transmitting or receiving signals and/or power. In these and other embodiments, one or more of the bond pads 109, 110 can serve as dummy pads (e.g., purely mechanical structures that are used to facilitate hybrid bonding the first substrate 101 to the second substrate 102). In some embodiments, a barrier material 117 (e.g., formed of tantalum (Ta), titanium (Ti), or another suitable material) can line sidewalls and/or a backside of the bond pads 109, 110, such as to prevent diffusion and/or migration of conductive materials of the bond pads 109, 110 into the dielectric layers 107 and/or 108, respectively, and/or into the substrates 101, 102, respectively.

As shown in FIG. 1A, the semiconductor device 100 further includes a barrier layer 115 disposed between corresponding ones of the bond pads 109, 110. In some embodiments, the barrier layer 115 can comprise a thin film material. In these and other embodiments, the barrier layer 115 can be formed of (a) one or more materials selected from platinum group metals (e.g., platinum (Pt), palladium (Pd), ruthenium (Ru)), (b) one or more two-dimensional materials (e.g., graphene, hexagonal boron nitride); and/or (c) one or more graphene-modified copper materials. Graphene-modified copper materials can include a copper-graphene (Cu-graphene) composite material and/or a Cu-graphene covetic material. Cu-graphene composites can refer to graphene-modified copper materials in which the copper and graphene do not form a chemical bond (e.g., where a copper base material is doped with individual sheets of graphene). Cu-graphene covetics can refer to graphene-modified copper materials in which the copper and graphene form a true chemical bond (e.g., with the copper and carbon in the graphene forming covalent and metallic bonds in a near-2D structure).

In some embodiments, the barrier layer 115 can be disposed on or over the bond pads 109, 110. For example, as discussed above, the bond pads 109, 110 can be formed of one or more conductive materials. Some conductive materials (e.g., copper) used to form one or more of the bond pads 109, 110 can be prone to oxidation. In these embodiments, the barrier layer 115 can be disposed on or over the bond pads 109, 110 (e.g., in, on, or over the first dielectric layer 107 and/or the second dielectric layer 108) to prevent, inhibit, or limit exposure of the bond pads 109, 110 to air and thereby prevent, inhibit, or limit oxidation of the bonds pads 109, 110. In other words, the barrier layer 115 can be positioned on or over one or more of the bond pads 109, 110 so as to reduce, minimize, or eliminate a surface area of the one or more bond pads 109 that would otherwise be exposed to air absent the barrier layer 115. The material in the barrier layer 115, however, must be selected to reduce (or avoid) interference with a bonding scheme (e.g., direct, metal-metal bonding) between the bonds pads 109, 110. As a specific example, prior to bonding the first substrate 101 to the second substrate 102, a barrier layer 115 can be disposed over one or more of the plurality of bond pads 109 and/or a barrier layer 115 can be disposed over one or more of the plurality of bond pads 110. Continuing with this example, when the first substrate 101 is bonded to the second substrate 102, corresponding ones of the plurality of bond pads 109 can be bonded to corresponding ones of the plurality of bond pads 110 via metal-to-metal bonds through the barrier layer 115 disposed over the plurality of bond pads 109 and/or a barrier layer 115 disposed over the plurality of bond pads 110. Because the barrier layer 115 can be used to prevent or inhibit oxidation of the bond pads 109 and/or 110 prior to the first substrate 101 being bonded to the second substrate 102, the barrier layer 115 is expected to mitigate (or obviate) the practice of using higher temperatures to overcome oxidation of the bond pads 109, 110 when bonding the first substrate 101 to the second substrate 102.

As shown in FIG. 1A, the barrier layer 115 can be disposed on or over the bond pads 109, 110 at discrete locations. In other words, the barrier layer 115 can be disposed on or over the bonds pads 109, 110 such that the barrier layer 115 (a) covers portions of the bond pads 109, 110 that would otherwise be exposed to air absent the barrier layer 115 but (b) does not extend across an entire width of the first substrate 101 and/or an entire width of the second substrate 102 measured in a direction extending generally from the left side of the first and second substrates 101, 102 in FIG. 1A to the right side of the first and second substrates 101, 102 in FIG. 1A. As such, after the first substrate 101 is bonded to the second substrate 102, each discrete portion of the barrier layer 115 can have a width (e.g., measured in the direction extending generally from the left side of the first and second substrates 101, 102 to the right ride of the first and second substrates 101, 102 in FIG. 1A) that is generally defined by or that corresponds to a width of a corresponding one of the upper bond pads 109 and a width of a corresponding one of the lower bond pads 110, as shown in FIG. 1A. In some embodiments, the barrier layer 115 can additionally, or alternatively, comprise a thickness of approximately 1 nm or more (e.g., 1nm to 5nm, or more), measured in a direction extending generally from the second side 106 of the second substrate 102 toward the second side 105 of the first substrate 101.

Consistent with the discussion above, certain conductive materials used to form one or more of the plurality of bond pads 109, 110 can be prone to diffusion and/or migration (e.g., movement of atoms under electric fields) into the first dielectric layer 107 and/or the second dielectric layer 108. Thus, in some embodiments, the barrier layer 115 can be used to prevent or inhibit diffusion and/or migration of the conductive materials from the bond pads 109, 110 into the dielectric layers 107 and/or 108. Additionally, or alternatively, the barrier layer 115 can be used to promote diffusion of the conductive materials across corresponding ones of the plurality of bond pads 109, 110.

For example, FIG. 1B is a partially schematic zoomed-in view of a portion of the semiconductor device 100 corresponding to the breakaway section 1B shown in FIG. 1A. As shown in FIG. 1B, although the bond pad 109b corresponds to (and is bonded to) the bond pad 110b, the bond pads 109b and 110b are not perfectly aligned with one another (e.g., due to manufacturing tolerances, equipment limitations, and/or different sizes/widths of the bond pads 109b, 110b). As a result, several interfaces can be formed at a bondline: (1) dielectric-to-dielectric bond regions 135 (e.g., oxide-to-oxide bond regions) formed at locations along the bondline where the first dielectric layer 107 is bonded to the second dielectric layer 108; (2) a first inhibited diffusion/migration region 125a formed at a location along the bondline where the barrier layer 115 (disposed on or over the bond pad 110b) is positioned between the bond pad 110b and the first dielectric layer 107; (3) a second inhibited diffusion/migration region 125b formed at a location along the bondline where the barrier layer 115 (disposed on or over the bond pad 109b) is positioned between the bond pad 109b and the second dielectric layer 108; and (4) an enhanced diffusion region 120 formed at a location along the bondline where (a) the bond pad 109b is aligned with the bond pad 110b and/or (b) the barrier layer 115 is disposed between bond pads 109b, 110b.

Referring to the first and second inhibited diffusion/migration regions 125a and 125b, the barrier layer 115 separates (i) conductive material (e.g., copper) used to form the bond pad 110b from the first dielectric layer 107 and (ii) conductive material (e.g., copper) used to form the bond pad 109b from the second dielectric layer 108, respectively. In particular, in the first inhibited diffusion/migration region 125a, the barrier layer 115 can prevent, inhibit, or reduce the likelihood of conductive material used to form the bond pad 110b from diffusing and/or migrating into the first dielectric layer 107. In addition, in the second inhibited diffusion region 125b, the barrier layer 115 can prevent, inhibit, or reduce the likelihood of conductive material used to form the bond pad 109b from diffusing and/or migrating into the second dielectric layer 108. In other words, in the first and second inhibited diffusion/migration regions 125a and 125b, the barrier layer 115 can hinder or block conductive material of the bond pads 110b and 109b, respectively, from diffusing and/or migrating across the bondline into the first and second dielectric layers 107 and 108, respectively. In this manner, the barrier layer 115 is expected to reduce the likelihood that diffusion and/or migration of conductive material of the bond pads 109b and 110b compromises the electrical and/or mechanical integrity of the semiconductor device 100.

Referring now to the enhanced diffusion region 120, the bond pad 109b can be bonded to the bond pad 110b, such as using a metal-to-metal bond. In embodiments in which the bond pads 109b and 110b are formed of copper, the metal-to-metal bond can include a copper-to-copper bond. As discussed above, the barrier layer 115 can be formed of a material that promotes diffusion of conductive materials across the bondline from one bond pad (e.g., the bond pad 109b) to a corresponding bond pad (e.g., the bond pad 110b) and/or vice versa. In other words, the enhanced diffusion region 120 can include a portion of the barrier layer 115 that, when subjected to heat and/or pressure (e.g., during a hybrid bonding or bonding procedure), encourages a migration of particles from the upper bond pad 109b into the lower bond pad 110b, and vice versa. For example, it is expected that, at least when subjected to heat and/or pressure (e.g., during a hybrid bonding or bonding procedure), particles of conductive material (e.g., copper) from the bond pad 109b can migrate across the barrier layer 115 and deeper into the bond pad 110b than would otherwise occur absent use of the barrier layer 115. Additionally, or alternatively, it is expected that, when subjected to heat and/or pressure (e.g., during a hybrid bonding or bonding procedure), particles of conductive material (e.g., copper) from the bond pad 110b can migrate across the barrier layer 115 and deeper into the bond pad 109b than would otherwise occur absent use of the barrier layer 115.

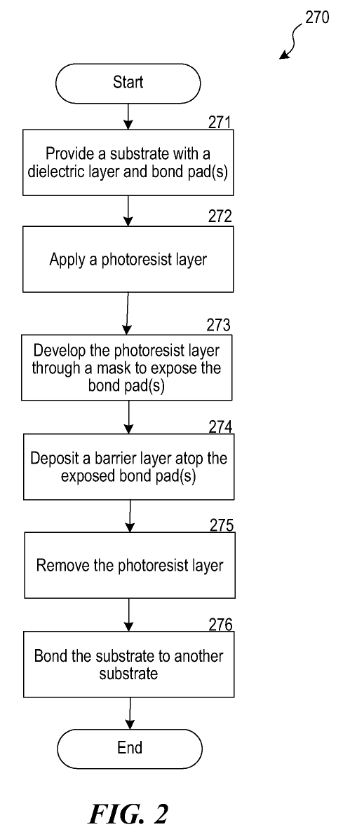

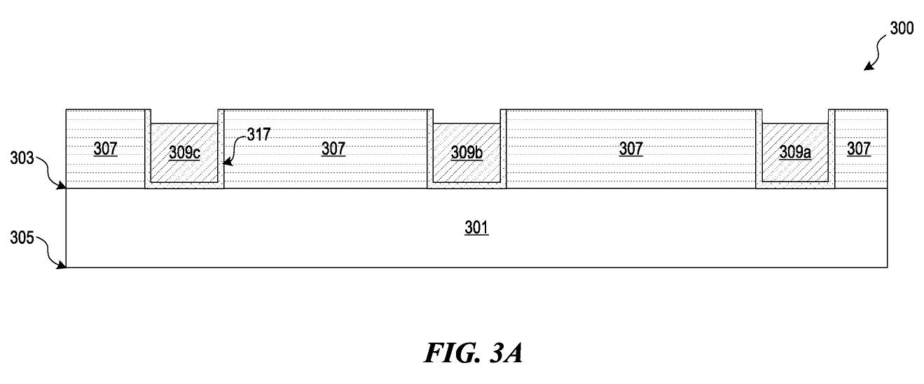

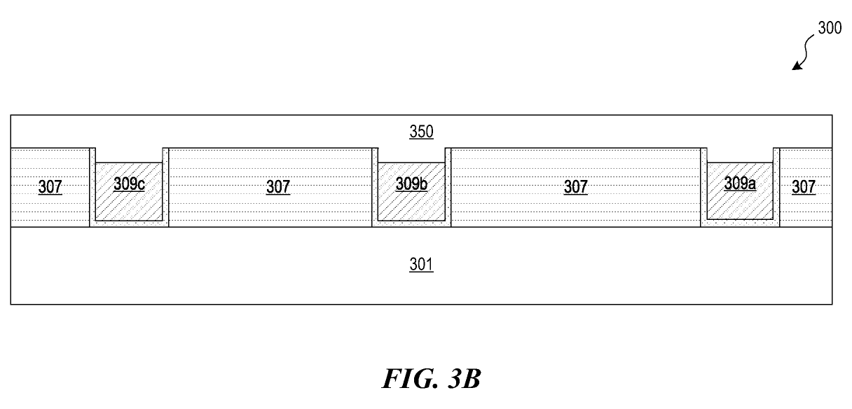

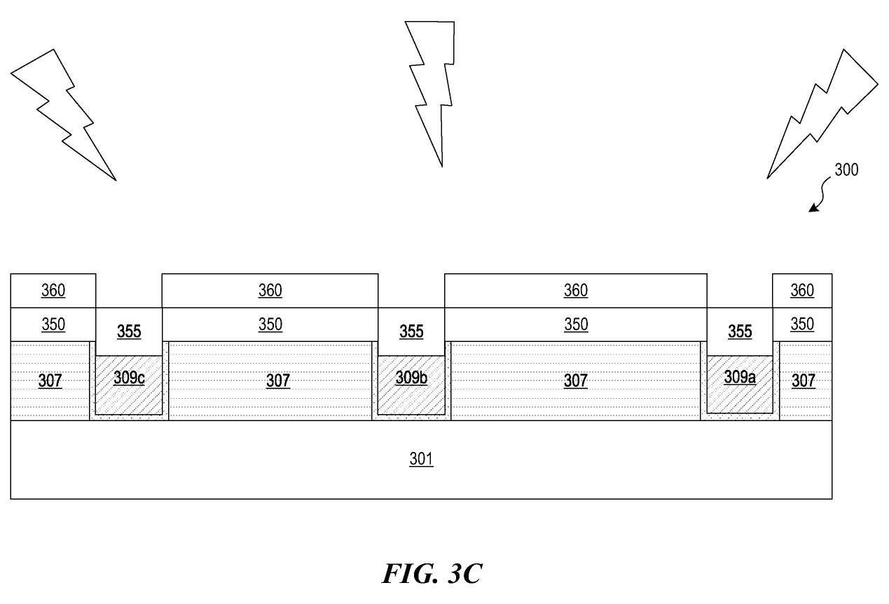

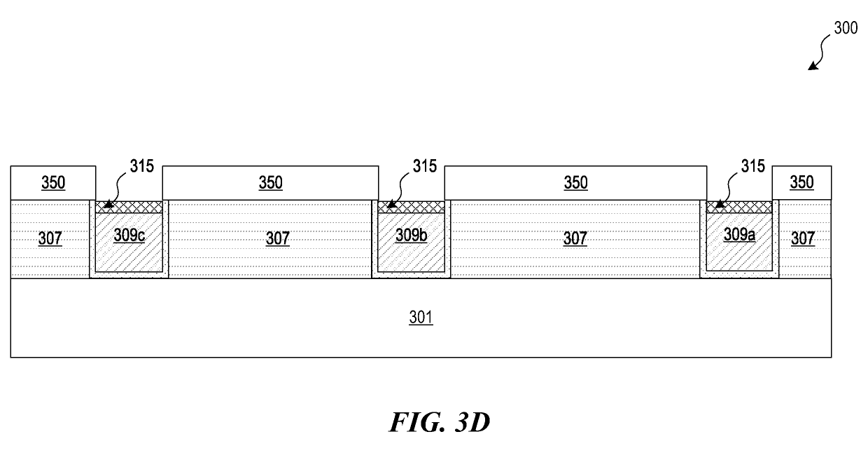

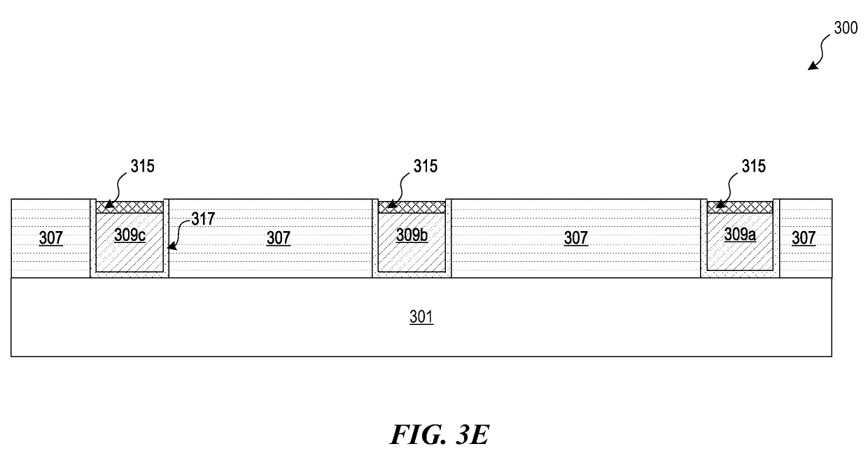

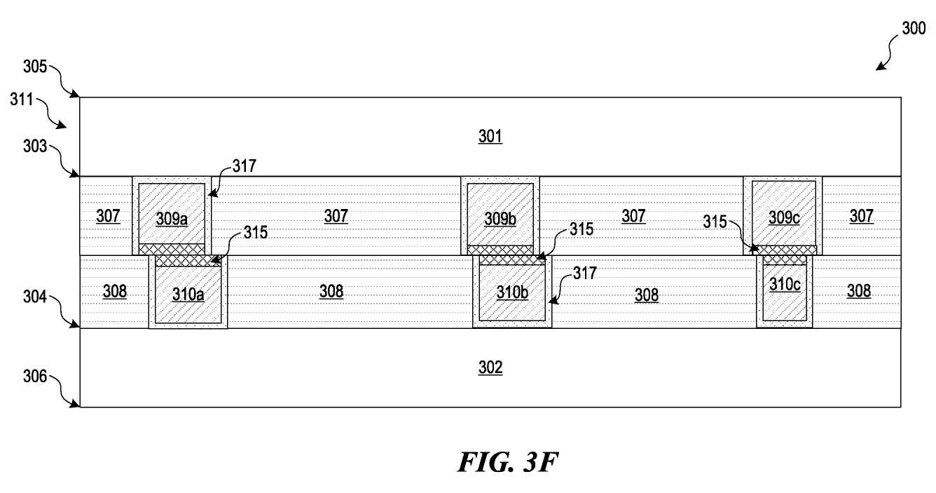

FIG. 2 is a flow diagram illustrating a method 270 of manufacturing a semiconductor device in accordance with various embodiments of the present technology. The semiconductor device can be the semiconductor device 100 of FIGS. 1A and 1B or another semiconductor device configured in accordance with various embodiments of the present technology. The method 270 is illustrated as a series of blocks or steps 271-276. All or a subset of one or more of the steps 271 276 can be executed in accordance with the description above and/or with the description that follows. Indeed, several of the steps 271-276 of the method 270 are described below with repeated reference to FIGS. 3A–3F that are partially schematic cross-sectional side views of a semiconductor device 300 at various stages of manufacturing in accordance with various embodiments of the present technology.

At step 271, the method 270 begins by providing a substrate. In some embodiments, the substrate can be a semiconductor wafer. In other embodiments, the substrate can be a semiconductor die, such as a memory die or chip. The substrate can include a dielectric layer and/or one or more bond pads at a first side of the substrate. Referring to FIG. 3A for the sake of example, providing a substrate at step 271 of the method 270 can include providing a substrate 301 having a first side 303 and a second side 305 opposite the first side 303. The substrate 301 can include a dielectric layer 307 and one or more bond pads 309 (identified individually in FIG. 3A as bond pads 309a-309c) at the first side 303 of the substrate 301. A barrier layer 317 can be used to line the sidewalls and/or backside of the bond pads 309.

At step 272, the method 270 continues by applying a photoresist layer on the substrate. Applying the photoresist layer can comprise depositing a layer of photoresist material over the dielectric layer and/or the bond pads, such as using a coating process (e.g., spin coating, spray coating, etc.). For example, the coating process can include placing the substrate onto a holding device (e.g., a vacuum chuck), depositing photoresist solution onto the substrate or onto the dielectric layer and/or bond pads disposed thereon, and spinning the substrate to spread the photoresist solution uniformly to produce a layer of photoresist. Referring to FIG. 3B for the sake of example, applying a photoresist layer at step 272 of the method 270 can include a depositing a photoresist layer 350 over the substrate 301, such as on top of or over the dielectric layer 307 and the one or more bond pads 309.

At step 273, the method 270 continues by developing the photoresist layer through a mask and exposing the one or more bond pads. Developing the photoresist layer can depositing or positioning a mask over the photoresist layer. For example, developing the photoresist layer can include aligning the mask with the substrate to ensure that those areas of the photoresist layer that are developed align with underlying bond pads that are to be exposed. The alignment step can comprise manual alignment or optical alignment. Additionally, or alternatively, developing the photoresist layer can include irradiating portions of the photoresist layer through the mask, such as using ultraviolet (UV) light. Exposing the one or more bond pads can include removing developed portions of the photoresist layer, such as using an etchant. Referring to FIG. 3C for the sake of example, developing the photoresist layer at step 273 of the method 270 can include disposing a mask 360 atop the photoresist layer 350. As shown, the mask 360 can include gaps or a stencil pattern that are generally aligned with the bond pads 309. Portions of the photoresist layer 350 can be developed by irradiating those portions through the gaps or stencil pattern in the mask 360, resulting in developed portions 355 of the photoresist layer 350. Although not shown in FIG. 3C, the developed portions 355 can be removed (e.g., using an etchant or other suitable technique), thereby exposing the underlying bond pads 309 through the mask 360 and recesses or apertures defined by remaining undeveloped portions of the photoresist layer 350.

At step 274, the method 270 continues by removing the mask and depositing a barrier layer atop the exposed bond pad(s). The barrier layer can comprise one or more of the following: a platinum group metal (e.g., platinum (Pt), palladium (Pd), ruthenium (Ru)), a 2D material (e.g., graphene, or hexagonal boron-nitride (h-BN)), a graphene-modified copper material (e.g., Cu-graphene composites, Cu-graphene covetics), or another suitable, refractory-type material that is stable under high temperatures. In some embodiments, the barrier layer can be deposited through the recesses or cavities formed in the photoresist layer by developing the photoresist layer and removing the developed portions at step 273 above. In these and other embodiments, the barrier layer can be deposited through the mask such that the mask can be removed after depositing the barrier layer. The barrier layer can be deposited using any suitable technique, such as physical vapor deposition (e.g., sputtering), chemical vapor deposition, plasma-enhanced chemical vapor deposition, atomic layer deposition, or electrochemical deposition. As discussed above, the barrier layer can comprise a thin film material. For example, the thin film material can have a thickness of approximately 1 nm or more (e.g., between about 1nm and about 5nm, or more). In a specific, non-limiting example, the barrier layer can be a thin film of a cu-graphene covetic material (e.g., a single sheet of a copper-graphene covetic material). In other embodiments, the thin film material can have a thickness between 0.25 nm and 1 nm. As a specific example, the barrier layer can be a single graphene sheet (e.g., of one atom thick), and can have a thickness of approximately 0.34nm.

Referring to FIG. 3D for the sake of example, depositing the barrier layer at step 274 of the method 270 can include depositing a barrier layer 315 through the photoresist layer 350 and atop the one or more bond pads 309. As shown in FIG. 3D, depositing the barrier layer 315 can include depositing the barrier layer 315 such that the barrier layer 315 is confined to regions corresponding to recesses or apertures formed in the photoresist layer 350 by developing and removing portions of the photoresist layer 350 at step 273 of the method 270 above. In other embodiments, depositing the barrier layer 315 can include depositing the barrier layer 315 such that the barrier layer 315 extends from a position atop the bond pads 309 to a height above the photoresist layer 350, such as on or over all or a portion of the photoresist layer 350. Consistent with the discussion above, the barrier layer 315 can be disposed on or over the bond pads 309 to prevent, inhibit, or limit exposure of the bond pads 309 to air, which is expected to prevent, inhibit, or limit oxidation of the bonds pads 309. In other words, the barrier layer 315 can be positioned on or over one or more of the bond pads 309 so as to reduce, minimize, or eliminate a surface area of the one or more bond pads 309 that would otherwise be exposed to air absent the barrier layer 315.

At step 275, the method 270 continues by removing the photoresist layer. In some embodiments, the photoresist layer can be removed using a photoresist liftoff technique, such as using a solvent (e.g., acetone, n-methyl-2-pyrrolidone (NMP), dimethyl sulfoxide (DMSO), ethyl lactate, or tetramethylammonium hydroxide (TMAH)) or by a dry stripping process (e.g., plasma ashing). Upon the removal of the photoresist layer, the barrier layer can remain disposed on or over the bond pads. Referring to FIG. 3E for the sake of example, step 275 of the method 270 can include removing the photoresist layer 350 (FIG. 3D) while leaving the barrier layer 315 disposed at discrete locations atop the one or more bond pads 309. As shown, the barrier layer 315 can have widths that closely match corresponding widths of the bond pads 309. In other embodiments, the barrier layer 315 can have widths that are larger than the widths of corresponding ones of the underlaying bond pads. In such embodiments, the barrier layer 315 can extend on or over at least part of a surface of the barrier layer 317 and/or at least part of a surface of the dielectric layer 307 that is laterally adjacent the corresponding bond pads 309.

At step 276, the method 270 continues by bonding the substrate to another substrate. In some embodiments, bonding the substrate to another substrate can include hybrid bonding the substrate to the other substrate. In these and other embodiments, bonding the substrate to another substrate can include cleaning and/or planarizing the bonding surface of the substrate (e.g., the side of the dielectric layer, the barrier layer, and/or the bond pads opposite the substrate) prior to bonding. In these and still other embodiments, bonding the substrate to another substrate can include applying a thin layer of adhesive on or over the substrate before the substrate is aligned with the other substrate and the substrates are pressed together. In some such embodiments, bonding the substrate to another substrate can include curing the adhesive. In other embodiments, bonding the substrate to the other substrate can be performed without using an adhesive.

Referring to FIG. 3F for the sake of example, bonding the substrate to another substrate at step 276 of the method 270 can include providing a second substrate 302 having a first side 304, a second side 306 opposite the first side 304, and a second dielectric layer 308 and one or more bond pads 310 (identified individually in FIG. 3F as bond pads 310a-310c) at the first side 304 of the substrate 302. In such embodiments, the substrate 301 can be referred to as a first substrate 301, and the dielectric layer 307 can be referred to as a first dielectric layer 307. The first substrate 301 and the second substrate 302 can be aligned and arranged in a stack 311. One or both of the substrates 301 and 302 can be wafers, die, or chips.

Bonding the first substrate 301 to the second substrate 302 can include hybrid bonding the first substrate 301 to the second substrate 302. After bonding the first substrate 301 to the second substrate 302, dielectric-to-dielectric bonds can exist between portions of the first dielectric layer 307 that are aligned with and interface portions of the second dielectric layer 308. In addition, after bonding the first substrate 301 to the second substrate 302, metal-to-metal bonds (e.g., copper-to-copper bonds) can exist between portions of the bond pads 309 that are aligned with portions of corresponding ones of the bond pads 310. Where the barrier layer 315 is disposed between a pair of corresponding bond pads 309, 310, the barrier layer 315 can contribute to formation of enhanced diffusion regions within which the metal-to-metal bonds can be enhanced. For example, the barrier layer 315 can promote a migration or diffusion of metal particles from one of the bond pads 309, 310 across the bondline and to the other of the bond pads 309, 310. Where corresponding bond pads 309 and 310 are not perfectly aligned with one another (e.g., bond pads 309a and 310a, bond pads 309b and 310b) or having differing widths (e.g., bond pads 309c and 310c), inhibited diffusion/migration regions can be formed at the bondline using at least a portion of the barrier layer 315. For example, at regions along the bondline where corresponding bond pads 309, 310 do not perfectly overlap one another and/or having different widths, the barrier layer 315 can be positioned between (a) at least a portion of the bond pad 309 and the second dielectric layer 308 and/or (b) at least a portion of the bond pad 310 and the first dielectric layer 307. In these embodiments, the barrier layer 315 can contribution to formation of the inhibited diffusion/migration regions by inhibiting, hindering, restricting, or preventing particles of conductive material (e.g., copper) from diffusing and/or migrating across the bondline from the bond pads 309 and 310 into the dielectric layers 308 and 307, respectively.

Although the steps 271-276 of the method 270 of FIG. 2 are discussed and illustrated in a particular order, the method 270 is not so limited. In other embodiments, all or a subset of one or more of the steps 271-276 of the method 270 can be performed in a different order. Moreover, a person of ordinary skill in the relevant art will recognize that the illustrated method 270 can be altered and still remain within these and other embodiments of the present technology. For example, all or a subset of one or more of the steps 271-276 of the method 270 illustrated in FIG. 2 can be omitted and/or repeated in some embodiments. As another example, the method 270 can include one or more additional steps than shown in FIG. 2.

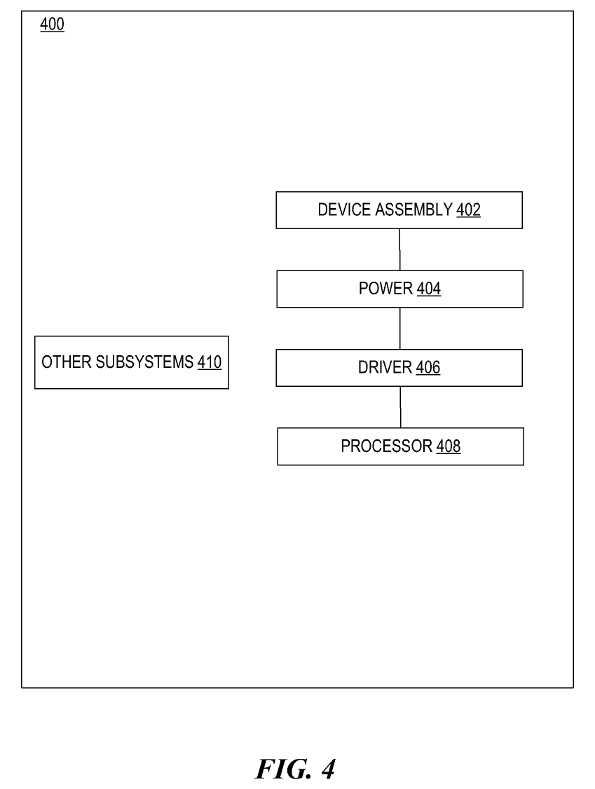

Any one of the semiconductor devices and semiconductor device assemblies described above with reference to FIGS. 1A–3F can be incorporated into any of a myriad of larger and/or more complex systems, a representative example of which is system 490 shown schematically in FIG. 4. The system 490 can include a semiconductor device assembly 400 (e.g., similar to the semiconductor devices 100 and/or 300 described above with reference to FIGS. 1A–3F), a power source 492, a driver 494, a processor 496, and/or other subsystems or components 498. The semiconductor device assembly 400 can include features generally similar to those of the semiconductor devices described above with reference to FIGS. 1A–3F. The resulting system 490 can perform any of a wide variety of functions, such as memory storage, data processing, and/or other suitable functions. Accordingly, representative systems 490 can include, without limitation, hand-held devices (e.g., mobile phones, tablets, digital readers, and digital audio players), computers, vehicles, appliances, and other products. Components of the system 490 may be housed in a single unit or distributed over multiple, interconnected units (e.g., through a communications network). The components of the system 490 can also include remote devices and any of a wide variety of computer readable media.

### C. Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications may be made without deviating from the disclosure or the technology. For example, one of ordinary skill

in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A semiconductor device, comprising:
a first substrate having a first side and a second side opposite the first side;
a second substrate having a first side and a second side opposite the first side;
a first dielectric layer at the first side of the first substrate;
a second dielectric layer at the first side of the second substrate;
a plurality of first bond pads disposed in or on the first dielectric layer;
a plurality of second bond pads disposed in or on the second dielectric layer; and
a barrier layer disposed between at least a portion of one of the plurality of first bond pads and at least a portion of a corresponding one of the plurality of second bond pads,
wherein the first substrate if hybrid bonded to the second substrate via the first and second dielectric layers, the plurality of first bond pads, and the plurality of second bond pads, and
wherein the barrier layer is configured to (a) inhibit diffusion and/or migration of a conductive material of the one of the plurality of first bond pads into the second dielectric layer and/or (b) inhibit diffusion and/or migration of a conductive material of the corresponding one of the plurality of second bond pads into the first dielectric layer.

2. The semiconductor device of claim 1, wherein the barrier layer comprises one or more platinum group metals.

3. The semiconductor device of claim 2, wherein the one or more platinum group metals comprise platinum, palladium, ruthenium, or any combination thereof.

4. The semiconductor device of claim 1, wherein the barrier layer comprises one or more two-dimensional materials comprising graphene and/or hexagonal boron nitride.

5. The semiconductor device of claim 1, wherein the barrier layer comprises a graphene-modified copper material.

6. The semiconductor device of claim 5, wherein the graphene-modified copper material comprises a copper-graphene covetic.

7. The semiconductor device of claim 1, wherein the barrier layer is a thin film material having a thickness between 0.25 nanometers and 5 nanometers.

8. The semiconductor device of claim 1, wherein the barrier layer is configured to promote diffusion of the conductive material of the one of the plurality of first bond pads into the corresponding one of the plurality of second bond pads.

9. The semiconductor device of claim 1, wherein the conductive material of the one of the plurality of first bond pads comprises copper and/or the conductive material of the corresponding one of the plurality of second bond pads comprises copper.

10. The semiconductor device of claim 1, wherein the barrier layer is disposed at discrete locations on or over the plurality of first bond pads.

11. The semiconductor device of claim 10, wherein each discrete location of the barrier layer has a width that corresponds to a width of a respective one of the plurality of first bond pads.

12. The semiconductor device of claim 1, wherein:
the one of the plurality of first bond pads is not fully aligned with the corresponding one of the plurality of second bond pads or has a first width that is different from a second width of the corresponding one of the plurality of second bond pads; and
at least a portion of the barrier layer is positioned between (i) the first dielectric layer and the corresponding one of the plurality of second bond pads or (ii) the second dielectric layer and the one of the plurality of first bond pads.

13. A method of manufacturing a semiconductor device, the method comprising:
providing a first substrate having a first side and a second side opposite the first side, the first substrate including a first dielectric layer and a plurality of first bond pads at the first side;
depositing a barrier layer on the plurality of first bond pads; and
bonding the first substrate to a second substrate, the second substrate having a first side and a second side opposite the first side and including a second dielectric layer and a plurality of second bond pads at the first side,
wherein, after bonding, the barrier layer is disposed between at least a portion of one of the plurality of first bond pads and at least a portion of a corresponding one of the plurality of second bond pads, and
wherein the barrier layer is configured to (a) inhibit diffusion and/or migration of a conductive material of the one of the plurality of first bond pads into the second dielectric layer and/or (b) inhibit diffusion and/or migration of a conductive material of the corresponding one of the plurality of second bond pads into the first dielectric layer.

14. The method of claim 13, wherein depositing the barrier layer comprises depositing a material comprising one or more platinum group metals, one or more two-dimensional materials, and/or a graphene-modified copper material.

15. The method of claim 14, wherein the material comprises the one or more platinum group metals, and wherein the one or more platinum group metals comprise platinum, palladium, ruthenium, or any combination thereof.

16. The method of claim 14, wherein the material comprises the one or more two-dimensional materials, and wherein the one or more two-dimensional materials comprise graphene and/or hexagonal boron nitride.

17. The method of claim 13, wherein the material comprises a copper-graphene covetic material.

18. The method of claim 13, wherein depositing the barrier layer comprises depositing a material configured to promote diffusion of a conductive material of the one of the plurality of first bond pads into the corresponding one of the plurality of second bond pads.

19. The method of claim 13, wherein depositing the barrier layer on the plurality of first bond pads includes covering the plurality of first bond pads with the barrier layer to inhibit oxidation of the plurality of first bond pads.

20. A semiconductor device, comprising:
a first substrate;
a second substrate bonded to the first substrate such that a bondline is positioned between the first substrate and the second substrate;
a plurality of first bond pads associated with the first substrate and disposed on a first side of the bondline opposite the second substrate;
a plurality of second bond pads associated with the second substrate and disposed on a second side of the bondline opposite the first side; and
a barrier layer disposed between at least a portion of one of the plurality of first bond pads and at least a portion of a corresponding one of the plurality of second bond pads,
wherein the bondline includes a metal-to-metal bond between the one of the plurality of first bond pads and the corresponding one of the plurality of second bond pads, and
wherein the barrier layer comprises a material configured to (a) inhibit diffusion and/or migration of conductive material of the one of the plurality of first bond pads across the bondline and into silicon or a dielectric material positioned on the second side of the bondline and/or (b) inhibit diffusion and/or migration of conductive material of the corresponding one of the plurality of second bond pads across the bondline and into silicon or a dielectric material positioned on the first side of the bondline.
